(19) United States
(12) Patent Application Publication
(10) Pub. No.: US 2024/0213210 A1
(43) Pub. Date: Jun. 27, 2024

(54) SYSTEM AND METHOD FOR USING ACOUSTIC WAVES TO COUNTERACT DEFORMATIONS DURING BONDING

(71) Applicant: Adeia Semiconductor Bonding Technologies Inc., San Jose, CA (US)

(72) Inventors: Belgacem Haba, Saratoga, CA (US); Pawel Mrozek, San Jose, CA (US)

(21) Appl. No.: 18/146,265

(22) Filed: Dec. 23, 2022

(51) Int. Cl. H01L 23/00

(52) U.S. Cl. CPC H01L 24/80; H01L 24/74; H01L 2224/802; H01L 2224/80895; H01L 2224/80896; H01L 2224/80908

(57) ABSTRACT

A method includes moving at least one of a first element and a second element to contact first regions of the first and second elements with one another while second regions of the first and second elements are not in contact with one another. The first regions directly bond to one another to form a bond interface without adhesive. The method further includes directly bonding the second regions of the first and second elements to one another without adhesive by controllably releasing one of the first element and the second element such that the bond interface and a boundary between the bond interface and the second regions not in contact with one another expands radially away from the first regions. The second regions have first vibrations within a bond initiation region bordering the boundary. The method further includes externally applying second vibrations to at least one of the first and second elements during the directly bonding. The second vibrations are in antiphase with the first vibrations in the bond initiation region.

### BACKGROUND

### Field

The field relates to systems and methods using acoustic waves to counteract deformations during wafer-to-wafer, die-to-die, and/or die-to-wafer bonding.

### Description of the Related Art

Semiconductor elements, such as semiconductor wafers or integrated device dies, can be stacked and directly bonded to one another without an adhesive, thereby forming a bonded structure. Nonconductive (e.g., dielectric; semiconductor) surfaces can be made extremely smooth and treated to enhance direct, covalent bonding, even at room temperature and without application of pressure beyond contact. In some hybrid direct bonded structures, nonconductive field regions of the elements can be directly bonded to one another, and corresponding conductive contact structures can be directly bonded to one another.

For example, a semiconductor element can be mounted to a carrier, such as a package substrate, an interposer, a reconstituted wafer or element, etc. A semiconductor element can be stacked on top of the semiconductor element (e.g., a first integrated device die can be stacked on a second integrated device die). Each of the semiconductor elements can have conductive pads for mechanically and electrically bonding the semiconductor elements to one another with the conductive pads mechanically and electrically bonded to one another.

### SUMMARY

In certain implementations, a method comprises supporting a first element and supporting a second element spaced from the first element. The method further comprises moving at least one of the first element and the second element to contact first regions of the first and second elements with one another while second regions of the first and second elements are not in contact with one another. The first regions directly bond to one another to form a bond interface without adhesive. The method further comprises directly bonding the second regions of the first and second elements to one another without adhesive by controllably releasing one of the first element and the second element such that the bond interface and a boundary between the bond interface and the second regions not in contact with one another expands radially away from the first regions. The second regions have first vibrations within a bond initiation region bordering the boundary. The method further comprises externally applying second vibrations to at least one of the first and second elements during said directly bonding. The second vibrations are in antiphase with the first vibrations in the bond initiation region.

In certain implementations, a method comprises bonding a first element to a second element in a bond initiation region. The bond initiation region has first vibrations. The method further comprises externally applying predetermined second vibrations to at least one of the first and second elements during said bonding. The second vibrations are configured to reduce distortions from the first vibrations.

In certain implementations, an apparatus comprises a first substrate support configured to hold a first substrate. The apparatus further comprises a second substrate support configured to hold a second substrate and to controllably release the second substrate. At least one of the first substrate support and the second substrate support is configured to move at least one of the first substrate and the second substrate to contact one another to initiate a bonding process of the first substrate to the second substrate. At least one of the first substrate and the second substrate undergoes first vibrations during the bonding process. The apparatus further comprises at least one transducer configured to controllably generate and transmit second vibrations to at least one of the first substrate and the second substrate during the bonding process. The second vibrations are configured to reduce vibration-induced distortions of the at least one of the first substrate and the second substrate during the bonding process.

### BRIEF DESCRIPTION OF THE DRAWINGS

Specific implementations will now be described with reference to the following drawings, which are provided by way of example, and not limitation.

FIG. 1A is a schematic cross sectional side view of two elements prior to bonding in accordance with certain implementations described herein.

FIG. 1B is a schematic cross sectional side view of the two elements of FIG. 1A after bonding in accordance with certain implementations described herein.

FIGS. 2A and 2B schematically illustrate an example direct bonding tool for bonding a first element with a second element in accordance with certain implementations described herein.

FIGS. 3A-3C schematically illustrate an example expansion of the bond interface during a direct bonding process of the first element with the second element in accordance with certain implementations described herein.

FIGS. 4A-4C schematically illustrate side views of the first and second elements at various moments during an example direct bonding process in accordance with certain implementations described herein.

FIG. 4D schematically illustrates a top view of the bond interface resulting from the direct bonding process of FIGS. 4A-4C in accordance with certain implementations described herein.

FIG. 4E schematically illustrates a top view of the second element and the bond interface at a moment during the direct bonding process in accordance with certain implementations described herein.

FIGS. 5A and 5B schematically illustrate two example apparatus in accordance with certain implementations described herein.

FIG. 6 illustrates a table and a plot of mode velocity as a function of frequency for a series of modes in accordance with certain implementations described herein.

FIG. 7 is a flow diagram of an example method in accordance with certain implementations described herein.

### DETAILED DESCRIPTION

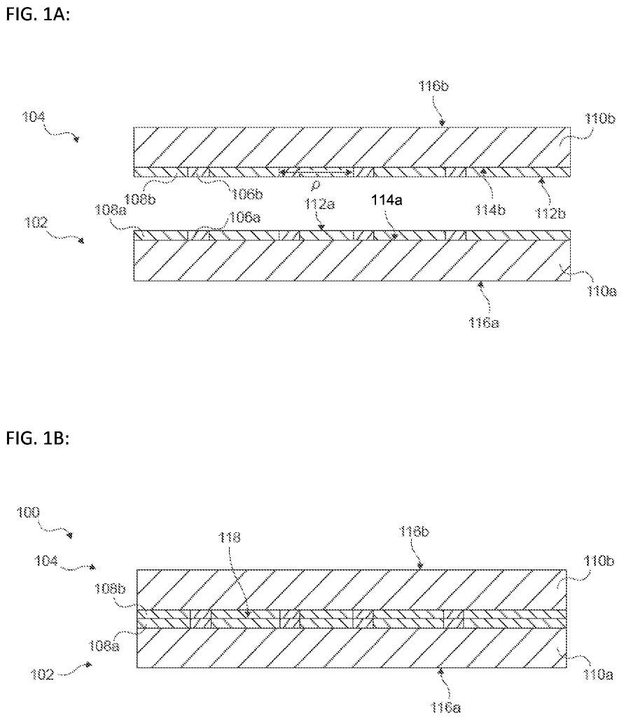

Various implementations disclosed herein relate to directly bonded structures in which two or more elements can be directly bonded to one another without an intervening adhesive. FIGS. 1A and 1B schematically illustrate cross-sectional side views of two elements 102, 104 prior to and after, respectively, a bonding process for forming a directly hybrid bonded structure 100 without an intervening adhesive in accordance with certain implementations described herein. As shown in FIGS. 1A and 1B, the bonded structure 100 can comprise a first element 102 and a second element 104 that are directly bonded to one another at a bond interface 118 without an intervening adhesive. The first and second elements 102, 104 can comprise microelectronic elements (e.g., semiconductor elements, including, for example, integrated device dies, wafers, passive devices, individual active devices such as power switches, etc.) that are stacked on or bonded to one another to form the bonded structure 100. For example, one or both of the first and second elements 102, 104 can comprise a thinned substrate or integrated device die having a thickness in a range of about 10 μm to 700 μm, in a range of about 10 μm to 300 μm, in a range of about 30 μm to 300 μm, or in a range of about 50 μm to 300 μm. Conductive features 106a (e.g., contact pads, exposed ends of vias (e.g., TSVs), or a through substrate electrodes) of the first element 102 can be electrically connected to corresponding conductive features 106b of the second element 104.

While FIGS. 1A and 1B schematically illustrate two elements 102, 104, any suitable number of elements can be stacked in the bonded structure 100 in accordance with certain implementations described herein. For example, a third element (not shown) can be stacked on the second element 104, a fourth element (not shown) can be stacked on the third element, and so forth. Additionally or alternatively, one or more additional elements (not shown) can be stacked laterally adjacent one another along the first element 102. In certain implementations, the laterally stacked additional element can be smaller than the second element 104 (e.g., the laterally stacked additional element can be two times smaller than the second element 104).

In certain implementations, the elements 102, 104 are directly bonded to one another without an adhesive. Bonding layers can be provided on front sides and/or back sides of the first and second elements 102, 104. For example, as schematically illustrated in FIGS. 1A and 1B, a first bonding layer 108a of the first element 102 can comprise a nonconductive field region of the first element 102 that includes a nonconductive or dielectric material (e.g., a dielectric material, such as silicon oxide, or an undoped semiconductor material, such as undoped silicon) and a second bonding layer 108b of the second element 104 can comprise a nonconductive field region of the second element 104 that includes a nonconductive or dielectric material (e.g., a dielectric material, such as silicon oxide, or an undoped semiconductor material, such as undoped silicon). The first and second bonding layers 108a. 108b can be disposed on respective front sides 114a, 114b of device portions 110a, 110b, such as semiconductor (e.g., silicon) portions, of the first and second elements 102, 103. Active devices and/or circuitry can be patterned and/or otherwise disposed in or on the device portions 110a, 110b, disposed at or near the front sides 114a, 114b of the device portions 110a, 110b, and/or at or near opposite backsides 116a, 116b of the device portions 110a, 110b.

The first and second bonding layers 108a, 108b can be directly bonded to one another without an adhesive (e.g., using dielectric-to-dielectric bonding techniques). For example, non-conductive or dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In certain implementations, the dielectric materials do not comprise polymer materials, such as epoxy, resin or molding materials.

In certain implementations, the device portions 110a, 110b can have significantly different coefficients of thermal expansion (CTEs) defining a heterogenous structure. The CTE difference between the device portions 110a, 110b, and particularly between bulk semiconductor (e.g., typically single crystal) portions of the device portions 110a, 110b can be greater than 5 ppm or greater than 10 ppm. For example, the CTE values for certain materials compatible with certain implementations described herein are in a range of 2 ppm to 10 ppm and the CTE difference between the device portions 110a, 110b can be in a range of 1 ppm to 10 ppm, 2 ppm to 10 ppm, or 5 ppm to 40 ppm. In certain implementations, one of the device portions 110a, 110b can comprise optoelectronic single crystal materials, including perovskite materials, that are useful for optical piezoelectric or pyroelectric applications, and the other of the device portions 110a, 110b can comprise a more conventional substrate material. For example, one of the device portions 110a, 110b can comprise lithium tantalate (LiTaO₃) or lithium niobate (LiNbO₃), and the other one of the device portions 110a. 110b can comprise silicon (Si), quartz, fused silica glass, sapphire, or a glass. In certain other implementations, one of the device portions 110a. 110b comprises a III-V single semiconductor material, such as gallium arsenide (GaAs) or gallium nitride (GaN), and the other one of the device portions 110a. 110b comprises a non-III-V semiconductor material, such as silicon (Si), or another materials with similar CTE, such as quartz, fused silica glass, sapphire, or a glass.

In certain implementations, direct hybrid bonds can be formed without an intervening adhesive. For example, bonding surfaces 112a, 112b of the nonconductive field regions of the bonding layers 108a, 108b can be polished to a high degree of smoothness (e.g., using chemical mechanical polishing (CMP)). The roughness of the polished surfaces 112a, 112b can be less than 30 Å rms. For example, the roughness of the polished surfaces 112a, 112b can be in a range of about 0.1 Å rms to 15 Å rms, 0.5 Å rms to 10 Å rms, or 1 Å rms to 5 Å rms. The surfaces 112a, 112b can be cleaned and exposed to a plasma and/or chemical etchants to activate the surfaces 112a. 112b. In certain implementations, the surfaces 112a, 112b can be terminated with a species after activation or during activation (e.g., during the plasma and/or etch processes). Without being limited by theory, in certain implementations, the activation process can be performed to break chemical bonds at the surfaces 112a, 112b, and the termination process can provide additional chemical species at the surfaces 112a, 112b that improves the bonding energy during direct bonding. In certain implementations, the activation and termination are provided in the same step (e.g., a plasma to activate and terminate the surfaces 112a, 112b). In certain other implementations, the surfaces 112a, 112b are terminated in a separate treatment from the activation process to provide the additional species for direct bonding. In certain implementations, the terminating species can comprise nitrogen. For example, one or both of the surfaces 112a, 112b can be exposed to a nitrogen-containing plasma (see, e.g., U.S. Pat. No. 7,387,944). Further, in certain implementations, one or both of the surfaces 112a, 112b are exposed to fluorine. For example, there may be one or multiple fluorine peaks at or near a bond interface 118 between the first and second elements 102, 104. Thus, in the directly bonded structure 100, the bond interface 118 between two nonconductive materials (e.g., the first and second bonding layers 108a, 108b) can comprise a very smooth interface with higher nitrogen content and/or fluorine peaks at the bond interface 118 (sec, e.g., U.S. Pat. No. 9,564,414). Additional examples of activation and/or termination treatments may be found throughout U.S. Pat. Nos. 9,564,414; 9,391,143; and 10,434,749, the entire contents of each of which are incorporated by reference herein in their entirety and for all purposes. The roughness of the polished surfaces 112a, 112b can be slightly rougher (e.g., about 1 Å rms to 30 Å rms, 3 Å rms to 20 Å rms, or possibly rougher) after an activation process.

In certain implementations, the conductive features 106a of the first element 102 are directly bonded to the corresponding conductive features 106b of the second element 104. For example, a direct hybrid bonding technique can be used to provide conductor-to-conductor direct bonds along the bond interface 118 that includes covalently direct bonded non-conductive-to-non-conductive (e.g., dielectric-to-dielectric) surfaces, prepared as described herein. In certain implementations, the conductor-to-conductor (e.g., conductive feature 106a to conductive feature 106b) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes. In direct hybrid bonding implementations described herein, conductive features are provided within the nonconductive field regions of the first and second bonding layers 108a, 108b, and both conductive and nonconductive features are prepared for direct bonding, such as by the planarization, activation and/or termination treatments described herein. Thus, the first and second bonding surfaces 108a, 108b prepared for direct bonding includes both conductive and nonconductive features.

For example, surfaces 112a, 112b of the nonconductive (e.g., dielectric) field regions (for example, inorganic dielectric surfaces) can be prepared and directly bonded to one another without an intervening adhesive as explained herein. Conductive contact features (e.g., conductive features 106a, 106b) can be at least partially surrounded by nonconductive (e.g., dielectric) field regions within the first and second bonding layers 108a. 108b and can directly bond to one another without an intervening adhesive. In certain implementations, the conductive features 106a, 106b can comprise discrete pads or traces at least partially embedded in the nonconductive material of the bonding layers 108a, 108b. In certain implementations, the conductive contact features comprise exposed contact surfaces of through substrate vias (e.g., through silicon vias (TSVs)). In certain implementations, the respective conductive features 106a, 106b can be recessed below the exterior (e.g., upper) surfaces (e.g., nonconductive bonding surfaces 112a, 112b) of the nonconductive portions of the first and second bonding layers 108a. 108b. For example, the recess can be less than 30 nm, less than 20 nm, less than 15 nm, or less than 10 nm, in a range of 2 nm to 20 nm, or in a range of 4 nm to 10 nm. In certain implementations, prior to direct bonding, the recesses in the opposing elements 102, 104 can be sized such that the total gap between opposing contact pads is less than 15 nm or less than 10 nm.

In certain implementations, the first and second bonding layers 108a, 108b are directly bonded to one another without an adhesive at room temperature and, subsequently, the bonded structure 100 can be annealed. Upon annealing, the conductive features 106a, 106b can expand and contact one another to form a metal-to-metal direct bond. In certain implementations, the materials of the conductive features 106a, 106b interdiffuse with one another during the annealing process. Beneficially, the use of Direct Bond Interconnect (DBI®) techniques commercially available from Adeia of San Jose, CA, can enable high density of conductive features 106a, 106b to be connected across the direct bond interface 118 (e.g., small or fine pitches for regular arrays). In certain implementations, the pitch of the conductive features 106a, 106b (e.g., conductive traces embedded in the bonding surface 108a, 108b of one of the bonded elements 102, 104) can be less than 100 microns or less than 10 microns or even less than 2 microns. For some applications, the ratio of the pitch of the conductive features 106a, 106b to one of the dimensions (e.g., a diameter) of the bonding pad is less than is less than 20, or less than 10, or less than 5, or less than 3 and sometimes desirably less than 2. In other applications, the width of the conductive traces embedded in the bonding surface 108a, 108b of one of the bonded elements 102, 104 is in a range between 0.3 to 20 microns (e.g., in a range of 0.3 to 3 microns). In certain implementations, the conductive features 106a, 106b and/or traces comprise copper or copper alloys, although other metals and alloys may be suitable. For example, the conductive features disclosed herein, such as the conductive features 106a, 106b, can comprise fine-grain metal (e.g., a fine-grain copper).

Thus, in direct bonding processes, the first element 102 can be directly bonded to the second element 104 without an intervening adhesive. In certain implementations, the first element 102 comprises a singulated element, such as a singulated integrated device die. In certain other implementations, the first element 102 comprises a carrier or substrate (e.g., a wafer) that includes a plurality (e.g., tens, hundreds, or more) of device regions that, when singulated, form a plurality of integrated device dies. Similarly, in certain implementations, the second element 104 comprises a singulated element, such as a singulated integrated device die. In certain other implementations, the second element 104 comprises a carrier or substrate (e.g., a wafer). Certain implementations disclosed herein can accordingly apply to wafer-to-wafer (W2W), die-to-die (D2D), or die-to-wafer (D2W) bonding processes. In wafer-to-wafer (W2W) processes, two or more wafers can be directly bonded to one another (e.g., direct hybrid bonded) and singulated using a suitable singulation process. After singulation, side edges of the singulated structure (e.g., the side edges of the two bonded elements 102, 104) can be substantially flush and can include markings indicative of the common singulation process for the bonded structure (e.g., saw markings if a saw singulation process is used).

As explained herein, the first and second elements 102, 104 can be directly bonded to one another without an adhesive, which is different from a deposition process and results in a structurally different interface compared to a deposition. In certain implementations, a width of the first element 102 in the bonded structure is similar to a width of the second element 104. In certain other implementations, a width of the first element 102 in the bonded structure 100 is different from a width of the second element 104. Similarly, the width or area of the larger of the first and second elements 102, 104 in the bonded structure can be at least 10% larger than the width or area of the smaller of the first and second elements 102, 104. The first and second elements 102, 104 can accordingly comprise non-deposited elements. Further, the directly bonded structures 100, unlike the deposited layers, can include a defect region along the bond interface 118 in which nanometer-scale voids (e.g., nanovoids) are present. The nanovoids can be formed due to activation of the bonding surfaces 112a, 112b (e.g., exposure to a plasma). As explained herein, the bond interface 118 can include concentration of materials from the activation and/or last chemical treatment processes. For example, in certain implementations that utilize a nitrogen plasma for activation, a nitrogen peak can be formed at the bond interface 118. The nitrogen peak can be detectable using secondary ion mass spectroscopy (SIMS) techniques. In certain implementations, for example, a nitrogen termination treatment (e.g., exposing the bonding surface to a nitrogen-containing plasma) can replace OH groups of a hydrolyzed (OH-terminated) surface with NH₂, NO, or NO₂ molecules, yielding a nitrogen-terminated surface. In certain implementations that utilize an oxygen plasma for activation, an oxygen peak can be formed at the bond interface 118. In certain implementations, the bond interface 118 can comprise silicon oxynitride, silicon oxycarbonitride, or silicon carbonitride. As explained herein, the direct bond can comprise a covalent bond, which is stronger than van Der Waals bonds. The bonding layers 108a, 108b can also comprise polished surfaces 112a, 112b that are planarized to a high degree of smoothness.

In certain implementations, the metal-to-metal bonds between the conductive features 106a, 106b can be joined such that metal grains grow into each other across the bond interface 118. In certain implementations, the metal is or includes copper, which can have grains oriented along the <111> crystal plane for improved copper diffusion across the bond interface 118. In certain implementations, the conductive features 106a, 106b include nanotwinned copper grain structure, which can aid in merging the conductive features during anneal. The bond interface 118 can extend substantially entirely to at least a portion of the bonded conductive features 106a, 106b, such that there is substantially no gap between the nonconductive bonding layers 108a, 108b at or near the bonded conductive features 106a, 106b. In certain implementations, a barrier layer may be provided under and/or laterally surrounding the conductive features 106a. 106b (e.g., which may include copper). In certain other implementations, however, there may be no barrier layer under the conductive features 106a, 106b, for example, as described in U.S. Pat. No. 11,195,748, which is incorporated by reference herein in its entirety and for all purposes.

Beneficially, the use of the hybrid bonding techniques described herein can enable extremely fine pitch between adjacent conductive features 106a, 106b, and/or small pad sizes. For example, in certain implementations, the pitch p (e.g., the distance from edge-to-edge or center-to-center, as shown in FIG. 1A) between adjacent conductive features 106a (or between adjacent conductive features 106b) can be in a range of 0.5 micron to 50 microns, in a range of 0.75 micron to 25 microns, in a range of 1 micron to 25 microns, in a range of 1 micron to 10 microns, or in a range of 1 micron to 5 microns. Further, a major lateral dimension (e.g., a pad diameter) can be small as well, e.g., in a range of 0.25 micron to 30 microns, in a range of 0.25 micron to 5 microns, or in a range of 0.5 micron to 5 microns.

Certain implementations disclosed herein relate to improved bonding methods and bonding tools for bonding two elements (e.g., two semiconductor elements; first and second elements 102, 104) without an intervening adhesive. Bonding tools used for wafer-to-wafer (W2W), die-to-wafer (D2W) and die-to-die (D2D) bonding typically use a vacuum force to pick up the die and to keep the die in place during die transportation and/or bonding. Vibrations propagating along at least one bonding surface 112a, 112b of the two elements 102. 104 during the bonding process (e.g., while the die is separating from the bonding tool and directly bonding to the substrate) can cause deformations of the at least one bonding surface 112a, 112b which can result in voids at the bond interface 118 between the two bonded elements 102, 104 of the bonded structure 100. Such voids can inhibit electrical connection between the first and second elements 102, 104 (e.g., a void can have a void size larger than a pad diameter and/or pitch of the conductive features of the two bonded elements 102, 104). For example, a relatively large bonding void disposed between pads or conductive features of the first and second elements 102, 104 can disrupt electrical signal between the opposing conductive features 106a, 106b, thus forming an open circuit. Such undesired open circuits can lead to lower electric device yield in the bonded structures 100, leading to a revenue loss.

Certain implementations described herein comprise systems and methods configured to improve control over the bonding process to reduce such voids. For example, by applying acoustic vibrations to one or both of the two elements 102, 104 during the bonding process to reduce (e.g., minimize; eliminate) vibrational distortions of the bonding surfaces 112a, 112b during the bonding process, certain implementations can reduce (e.g., minimize; eliminate) void formation at the direct bond interface 118 between the two elements 102, 104 (e.g., a die and a substrate, which can be, for example, a second die, a wafer or a carrier of another type). The applied vibrations can comprise deflections of the surfaces that are substantially normal to the surfaces, in contrast to vibrations used in ultrasonic bonding which comprise deflections that are substantially parallel to the surfaces. While certain implementations are described herein with reference to direct bonding processes, certain other implementations can be used with other types of bonding processes and with any semiconductor wafers or dies (e.g., Si, Si—Ge, GaAs, Ga₂O₃, GaN, glass, etc.).

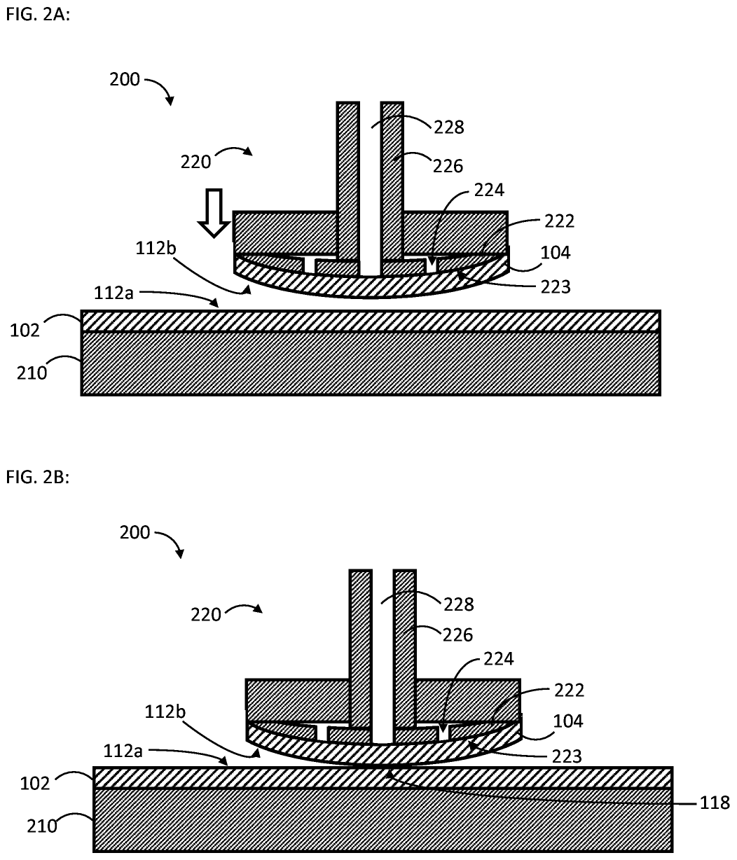

FIGS. 2A and 2B schematically illustrate an example direct bonding tool 200 for bonding a first element 102 (e.g., a singulated integrated device die comprising active circuitry) with a second element 104 (e.g., a substrate such as a wafer) in accordance with certain implementations described herein. FIG. 2A shows the direct bonding tool 200 prior to the initial formation of the bond interface 118 and FIG. 2B shows the direct bonding tool 200 at the initial formation of the bond interface 118. The bonding tool 200 comprises a first portion 210 configured to hold the first element 102 and a second portion 220 configured to hold the second element 104. The second portion 220 comprises a plate 222 with a plurality of vacuum holes 224 (e.g., channels), the plate 222 comprising a plate surface 223 configured to contact the second element 104. The plate 222 is connected to a shank 226 (e.g., shaft) having a central vacuum channel 228. The vacuum holes 224 can be in fluid communication with the central vacuum channel 228 by one or more transverse passages. As shown in FIGS. 2A and 2B, the plate surface 223 can be curved to facilitate center-first contact. The bonding tool 200 of certain implementations is configured to use a vacuum force during transport, alignment, and positioning of the second element 104 relative to the first element 102. For example, the vacuum force can be applied to a central region of the second element 104 through the central vacuum channel 228, and to peripheral regions of the second element 104 through the vacuum holes 224, thereby holding the backside 116b in contact with the plate surface 223. To bond the second element 104 to the first element 102, the shank 226 can be translated downward towards the bonding surface 112a. The shank 228 can comprise a sensor (not shown) configured to measure the resistance force encountered while translating the shank 226 downward. The shank 228 can continue to translate downwards until a pre-set or predetermined bond initiation force (e.g., initiation of the bond interface 118) is applied by the first and second portions 210, 220 pressing the bonding surfaces 112a, 112b together (sec, e.g., FIG. 2B) for a single point bond initiation. The vacuum force can then be reduced (e.g., removed) to controllably release the second element 104 from the second portion 220, thereby allowing a bonding wave to propagate from the single point bond initiation, enlarging the area of the bond interface 118 between the bonding surfaces 112a, 112b. While FIGS. 2A and 2B show an example direct bonding tool 200 that utilizes vacuum forces for holding the first element 102 and/or the second element 104, other types of direct bonding tools 200 that do not utilize vacuum forces (e.g., such as electrostatic chucks, Bernoulli principle wafer and die holders, and other tools) are also compatible with certain implementations described herein.

In certain implementations, the bonding tool 200 comprises a control system configured to provide a controllable delay between applying the bond initiation force and releasing the vacuum force, and a controllable delay between releasing the vacuum force and moving the second portion 220 upwards. The center vacuum channel 228 can be switched between applying a vacuum force and applying a pressure to the backside 116b (e.g., by flowing a pressurized gas into the center vacuum channel 228).

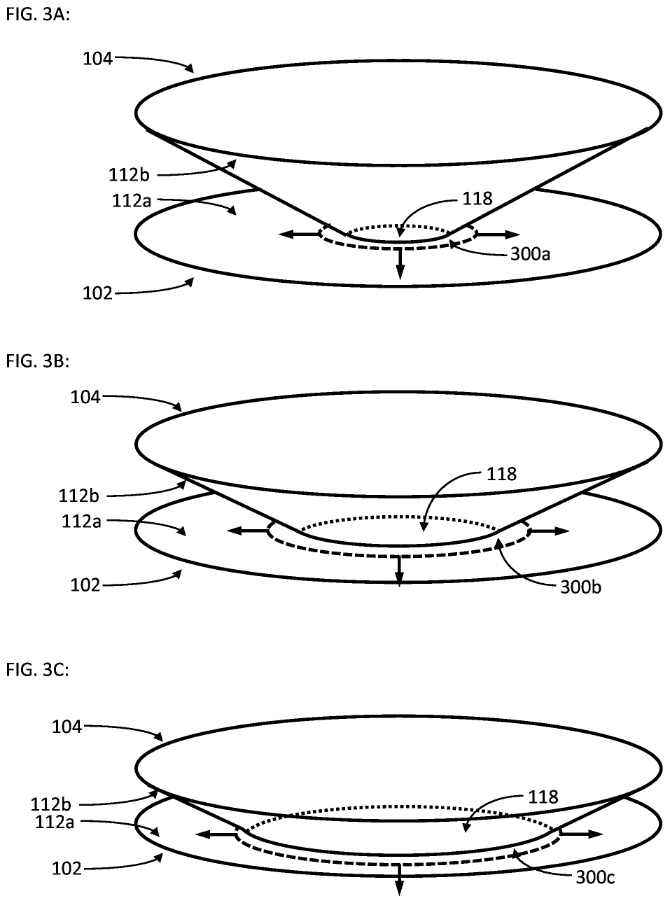

FIGS. 3A-3C schematically illustrate an example expansion of the bond interface 118 during a direct bonding process of the first element 102 with the second element 104 in accordance with certain implementations described herein. The direct bonding process can be initiated (see, e.g., FIG. 2B) with the first element 102 held by the first portion 210 of the bonding tool 200 (not shown in FIG. 3A-3C) with the bonding surface 112a substantially flat, the second element 104 held by the second portion 220 of the bonding tool 200 with the bonding surface 112b bent (e.g., curved due to the previously initiated bonding process at the wafer center), and the central regions of the first and second elements 102, 104 in contact with one another. After release of the peripheral regions of the second element 104 from the second portion 220, at a first moment during the direct bonding process (see, e.g., FIG. 3A), the bond interface 118 has a first diameter and is surrounded by an annular bond initiation region 300a in which the bonding surfaces 112a, 112b are not yet in contact, but will next contact one another (sec, e.g., A. W. Leissa, “Vibration of Plates,” Scientific and Technical Information Division, National Aeronautics and Space Administration (1969)). At a second moment after the first moment (see, e.g., FIG. 3B), the bond interface 118 has a second diameter greater than the first diameter (after the direct bonding occurs in the bond initiation region 300a) and is surrounded by the bond initiation region 300b. At a third moment after the second moment (see, e.g., FIG. 3C), the bond interface 118 has a third diameter greater than the second diameter (after the direct bonding occurs in the bond initiation region 300b) and is surrounded by the bond initiation region 300c. In this way, the bond initiation region 300 propagates outwardly (e.g., expands radially away from the central regions of the first and second elements 102, 104) until the bond interface 118 extends to the periphery of the first element 102 and/or the second element 104.

In certain implementations, during the direct bonding process, vibrations of at least one of the bonding surfaces 112a, 112b are created (e.g., by the bonding front creating a circular clastic deformation in the wafer, which propagates outward having acoustic frequencies) and propagate along and deform the at least one of the bonding surfaces 112a. 112b, creating deformations 400 of the at least one of the bonding surfaces 112a, 112b in the bond initiation region 300 (e.g., vertical deformations in a direction substantially perpendicular to the at least one of the bonding surfaces 112a, 112b). The bonding front can have a travelling speed in a range of 1 cm/s to 5 cm/s, while the elastic deformation waves can have speeds in a range of 10 m/s to 300 m/s. For example, the vibrations can be created by contacting the first and second elements 102, 104 with one another and/or by releasing the second element 104 from the second portion 220 of the bonding tool 200. These vibrations also are reflected or otherwise affected by boundaries of the first and second elements 102, 104 as well as by other mechanical constraints (e.g., the outer perimeter of the bond interface 118; contact points of the first and second elements 102, 104 with one another and/or with the first and second portions 210, 220 of the bonding tool 200) and these vibrations can constructively and destructively interfere with one another to produce the deformations 400 in the bond initiation region 300. For example, portions of the first and second elements 102, 104 in regions already bonded together (e.g., having the bond interface 118 radially inward from the bond initiation region 300) have different vibrational properties than do portions of the first and second elements 102, 104 that are not yet bonded together, and the boundary between these portions can reflect or otherwise affect the propagating vibrations. Upon the direct bonding occurring in the bond initiation region 300, the deformations 400 can cause the bond interface 118 to include voids, contaminant inclusions, and/or lateral displacements between the structures of the bonding surfaces 112a, 112b to be bonded to one another (e.g., alignment or registry errors between the structures).

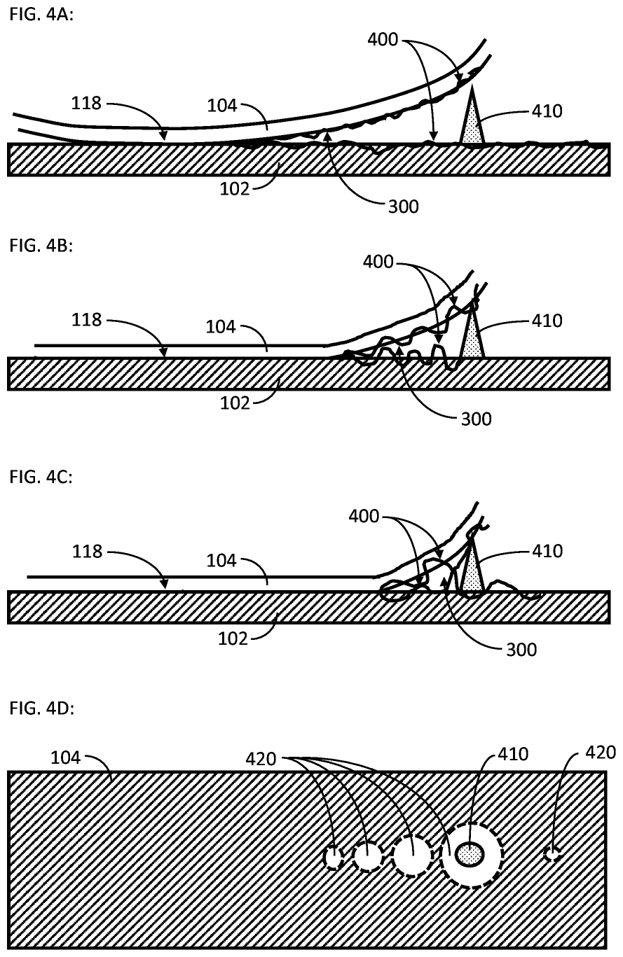

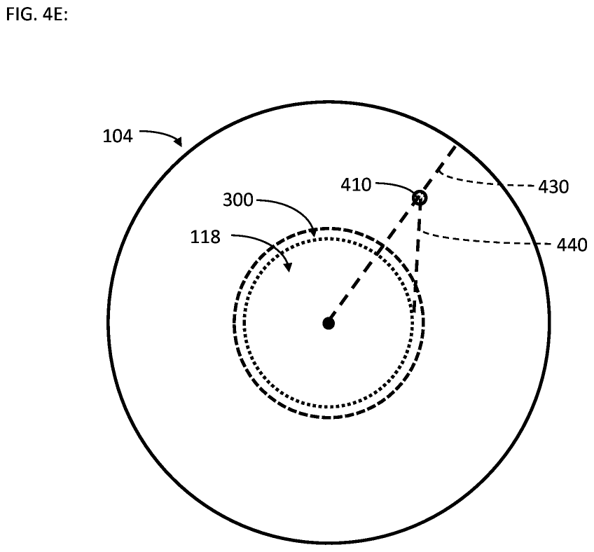

FIGS. 4A-4C schematically illustrate side views of the first and second elements 102, 104 at various moments during an example direct bonding process in accordance with certain implementations described herein. In the example direct bonding process of FIGS. 4A-4C, a contamination particle 410 (e.g., debris particle) exists on the bonding surface 112a. As shown in FIG. 4A, at a first moment during the direct bonding process, the bond interface 118 has a first diameter (sec, e.g., FIG. 3A), and the vibrations of the bonding surfaces 112a, 112b are reflected or otherwise affected by the various boundaries and mechanical constraints (e.g., outer perimeters of the first and second elements 102, 104; boundary between the bond interface 118 and the bond initiation region 300a), causing the deformations 400 within the bond initiation region 300a to have a first range of magnitudes when the direct bonding occurs in the bond initiation region 300. As shown in FIG. 4B, at a second moment during the direct bonding process after the first moment, the bond interface 118 has a second diameter greater than the first diameter (sec, e.g., FIG. 3B), and the bonding surface 112b contacts the contamination particle 410. Besides the changing boundary between the expanding bond interface 118 and the bond initiation region 300, this contact gives rise to additional reflections and/or scattering of the vibrations, which, as shown in FIG. 4B, cause the deformations 400 within the bond initiation region 300 to have a second range of magnitudes that include greater magnitudes than those of the first range of magnitudes. As shown in FIG. 4C, at a third moment during the direct bonding process after the second moment, the bond interface 118 has a third diameter greater than the second diameter (see, e.g., FIG. 3C), and the changing boundary between the expanding bond interface 118 and the bond initiation region 300 causes the deformations 400 within the bond initiation region 300 to have a third range of magnitudes that include greater magnitudes than those of the second range of magnitudes.

FIG. 4D schematically illustrates a top view of the bond interface 118 resulting from the direct bonding process of FIGS. 4A-4C in accordance with certain implementations described herein. The bond interface 118 includes a plurality of voids 420, one of which includes the contamination particle 410. Even without the contamination particle 410, the vibrations of the bonding surfaces 112a, 112b and their interactions with the changing boundaries and other mechanical constraints during the direct bonding process can give rise to the encapsulated contamination particles 410, voids 420, and/or lateral displacements within the bond interface 118. FIG. 4E schematically illustrates a top view of the second element 104 and the bond interface 118 at a moment during the direct bonding process (e.g., see FIG. 3B) in accordance with certain implementations described herein. In certain implementations, the vibrations propagating substantially along a direction 430 intersecting the contamination particle 410 and substantially perpendicular to the perimeters of the bond interface 118 and the second element 104 can interfere with one another and with vibrations reflecting from the contamination particle 410 such that the deformations 400 along the direction 420 are larger than those along other directions and the voids 420 can be formed at the bond interface 118 primarily along the direction 420. In certain other implementations, other directions 440 intersecting the contamination particle 410 have large deformations 400 resulting in one or more voids 420 being formed at the bond interface 118.

Besides contributing to void formation at the bond interface 118, the vibrations of at least one of the bonding surfaces 112a, 112b can contribute to lateral displacements between the structures of the bonding surfaces 112a, 112b to be bonded to one another (e.g., alignment or registry errors between the structures). Sec, e.g., K. Lim et al., “Design and Simulation of Symmetric Wafer-to-Wafer Bonding Compensating [sic] a Gravity Effect,” 2020 IEEE 7th Electronic Components and Technology Conference (ECTC), pp. 1480-1485 (2020).

In certain implementations, the amplitudes, phases, and/or frequency distribution functions of the vibrations occurring during the direct bonding process can be calculated as functions of the changing boundaries and other mechanical constraints of the first and second elements 102, 104 (e.g., as functions of time during the direct bonding process). For example, mathematical modeling (e.g., amplitude and Fourier frequency analysis) can be used to calculate the vibrations of the first element 102 and/or the second element 104 (e.g., described as a linear superposition of a series of vibration modes or standing waves of a thin plate or membrane). Sec, e.g., T. D. Rossing and N. H. Fletcher, “Principles of Vibration and Sound,” second ed., Springer-Verlag, New York (2004); A. W. Leissa, “Vibration of Plates,” Scientific and Technical Information Division, National Aeronautics and Space Administration (1969).

In certain implementations, such calculations, performed prior to initiating the direct bonding process, can be used as input for generating second vibrations (e.g., using at least one external transducer) that are applied to the first element 102 and/or second element 104, the second vibrations configured to counteract the vibrations occurring during the direct bonding process to reduce the deformations 400 in the bond initiation region 300 and the concomitant voids 420, encapsulation of contamination particles 410, and/or lateral displacements between the first and second elements 102, 104 at the bond interface 118. The applied second vibrations can have deflections of the surfaces that are substantially normal to the bonding surfaces that counteract deflections of the bonding surfaces caused by the first vibrations and that are substantially normal to the bonding surfaces. Such applied vibrations (e.g., normal vibrations) are different from vibrations used in ultrasonic bonding which comprise deflections that are substantially parallel to the surfaces (e.g., horizontal vibrations) and that are not configured to counteract the vibrations occurring during the direct bonding process.

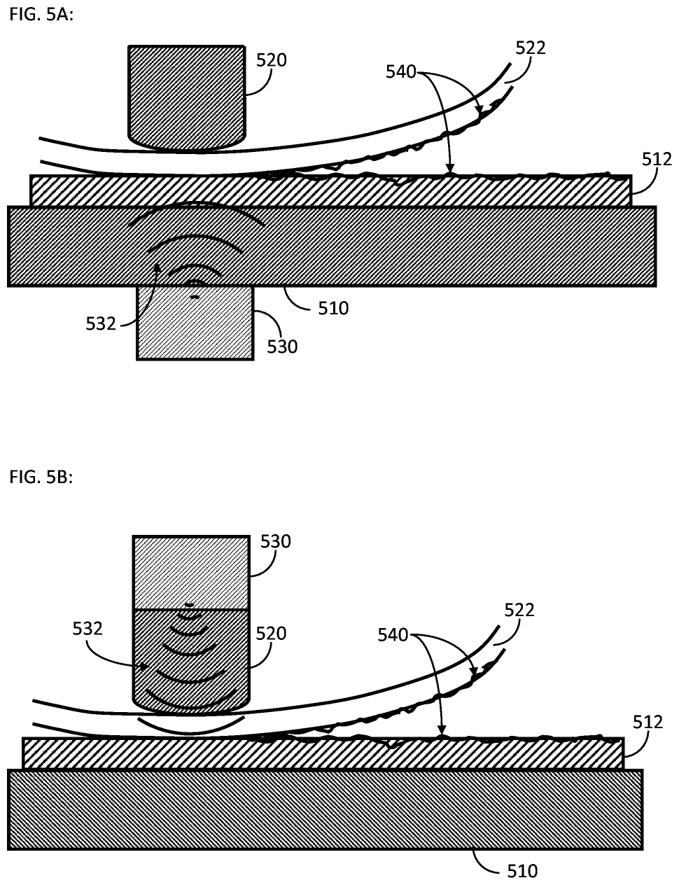

FIGS. 5A and 5B schematically illustrate two example apparatus 500 in accordance with certain implementations described herein. The apparatus 500 comprises a first substrate support 510 (e.g., first portion 210 of the bonding tool 200) configured to hold a first substrate 512 (e.g., first element 102) and a second substrate support 520 (e.g., second portion 220 of the bonding tool 200) configured to hold a second substrate 522 (e.g., second element 104) and to controllably release the second substrate 522. At least one of the first substrate support 510 and the second substrate support 520 is configured to move at least one of the first substrate 512 and the second substrate 522 to contact one another (e.g., at a central region) to initiate a direct bonding process of the first substrate 512 to the second substrate 522. At least one of the first substrate 512 and the second substrate 522 undergoes first vibrations during the direct bonding process (e.g., having acoustic frequencies). The apparatus 500 further comprises at least one transducer 530 configured to controllably generate and transmit second vibrations 532 (e.g., having acoustic frequencies) to at least one of the first substrate 512 and the second substrate 522 during the direct bonding process. The second vibrations 532 are configured to reduce vibration-induced distortions 540 (e.g., deformations 400) of the at least one of the first substrate 512 and the second substrate 522 during the direct bonding process. While the example apparatus 500 is described herein as comprising the bonding tool 200 of FIGS. 2A and 2B, in certain other implementations, the apparatus 500 comprises other types and/or configurations of a bonding tool.

In certain implementations, as schematically illustrated by FIG. 5A, the at least one transducer 530 is in mechanical communication with the first substrate support 510 and the second vibrations 532 propagate from the at least one transducer 530, through at least a portion of the first substrate support 510, to the first substrate 512 or to both the first and second substrates 512, 522. In certain other implementations, the at least one transducer 530 is a component of the first substrate support 510 and is in direct contact with the first substrate 512 such that the second vibrations 532 propagate from the at least one transducer 530 directly to the first substrate 512. In certain implementations, as schematically illustrated by FIG. 5B, the at least one transducer 540 is in mechanical communication with the second substrate support 520 and the second vibrations 532 propagate from the at least one transducer 530, through at least a portion of the second substrate support 520, to the second substrate 522 or to both the first and second substrates 512, 522. In certain other implementations, the at least one transducer 530 is a component of the second substrate support 520 and is in direct contact with the second substrate 522 such that the second vibrations 532 propagate from the at least one transducer 530 directly to the second substrate 522. In certain implementations, the at least one transducer 530 is in mechanical communication with both the first substrate support 510 and the second substrate support 520 (e.g., two transducers, each in mechanical communication with a corresponding one of the first substrate 512 and the second substrate 522). In certain implementations, the at least one transducer 530 is centrally located with respect to the at least one of the first and second substrates 510, 520 (sec, e.g., FIGS. 5A and 5B), while in certain other implementations the at least one transducer 530 is spaced away from a center region of the at least one of the first and second substrates 510, 520.

In certain implementations, the at least one transducer 530 is separate from both the first substrate support 510 and the second substrate support 520 (e.g., not in mechanical communication with either the first substrate support 510 or the second substrate support 520). For example, the at least one transducer 530 can comprise at least one speaker configured to generate and transmit sonic (e.g., acoustic) vibrations through air to at least one of the first substrate 512 and the second substrate 522, the sonic vibrations configured to generate the second vibrations 532.

In certain implementations, the at least one transducer 530 comprises at least one piezoelectric transducer while in certain other implementations, the at least one transducer 530 comprises at least one capacitive transducer and/or at least one magnetostriction transducer. The at least one transducer 530 can generate second vibrations 532 having an acoustic frequency range of less than 10 kHz (e.g., less than 1 kHz; less than 500 Hz).

In certain implementations, the second vibrations 532 are configured to destructively interfere with the first vibrations (e.g., of the first substrate 512 and/or of the second substrate 522) in the bond initiation region during the direct bonding process. The first vibrations can be modeled to have a predetermined first modal distribution F₁(t) as a function of time during the direct bonding process and the second vibrations 532 can have a second modal distribution F₂(t) as a function of time during the direct bonding process, at least a portion of the second modal distribution in antiphase with at least a portion of the first modal distribution F₁(t). For example, the first modal distribution F₁(t) can comprise a first linear superposition of a plurality of vibration modes (e.g., about 5-10 vibrational modes), each vibration mode having a corresponding amplitude and phase as a function of time and the second modal distribution F₂(t) can comprise a second linear superposition of the plurality of vibrational modes of the first vibrations, but with each vibration mode having substantially equal amplitudes and substantially opposite phases as those of the first vibrations.

In certain implementations, the at least one transducer 530 comprises control circuitry (e.g., microprocessor) configured to control the at least one transducer 530 to generate the second vibrations 532. For example, the control circuitry can be configured to receive, from computer memory, information indicative of the second vibrations 532 to be generated (e.g., indicative of the predetermined first modal distribution F₁(t) as a function of time during the direct bonding process) and the information can be used as input to the control circuitry for generating the second vibrations 532 to have the second modal distribution F₂(t).

For another example, the apparatus 500 can comprise calculation circuitry configured receive information regarding various parameters that affect the characteristics of the first vibrations (e.g., the sizes, thicknesses, and/or materials of the first substrate 512 and the second substrate 522; dimensions and other properties of the first substrate support 510 and/or the second substrate support 520; release timing or other operational parameters of the apparatus 500; temperature or other environmental conditions) and to calculate the dynamically changing first vibrations expected to occur as a function of time during the direct bonding process (e.g., the amplitudes, phases, and frequencies of the vibrational modes changing as a function of time). Such information can be provided by at least one of user input, computer memory, and sensors (e.g., thermal sensors; pressure sensors) of the apparatus 500. In certain implementations, the calculation circuitry can utilize feedback information from at least one sensor of the apparatus 500 during the course of the direct bonding process to monitor conditions during the direct bonding process (e.g., the deformations 400 from the combination of the first vibrations and the second vibrations 532) and/or to dynamically modify the second vibrations 532 to reduce the deformations 400.

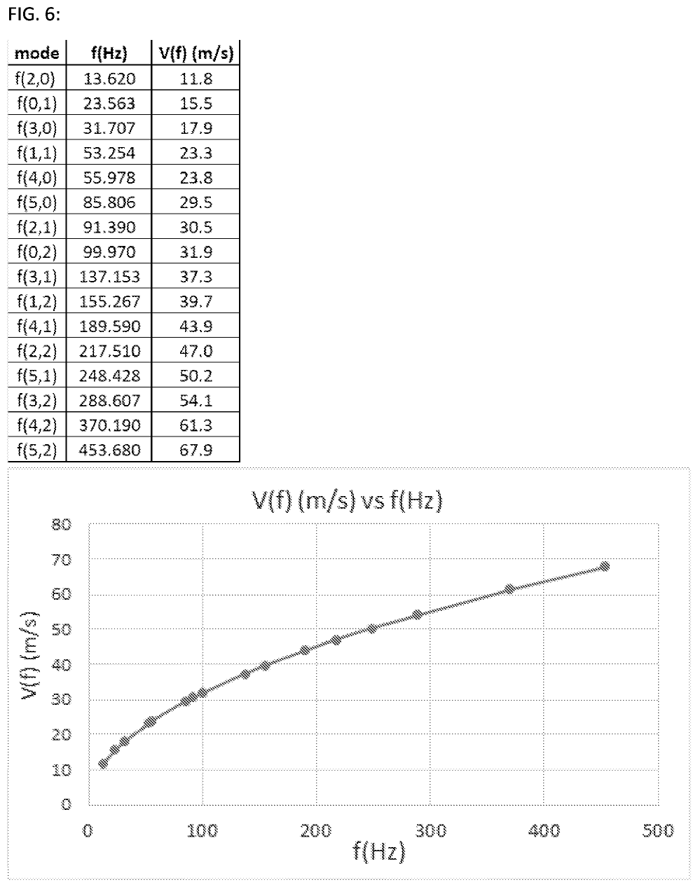

In certain implementations in which the direct bonding process is relatively slow (e.g., speed of the expanding boundary of the bond interface 118 of about 1 to 2 cm/s) compared to the speed of propagation of the first vibrations and the second vibrations 532 (e.g., speed in a range of 10 m/s to 300 m/s), the predetermined first modal distribution F₁(t) can be calculated by treating the first and second substrates 512, 522 at each moment during the direct bonding process as being static (e.g., the boundary conditions for the calculation at each moment are fixed, but change from one moment to the next). In certain implementations, the calculations can take into account the dispersive nature of the vibrations (e.g., each mode having a velocity that is dependent on the frequency of the mode). For example, FIG. 6 illustrates a table and a plot of mode velocity as a function of frequency for a series of modes in accordance with certain implementations described herein (sec, e.g., A. W. Leissa, “Vibration of Plates,” Scientific and Technical Information Division, National Aeronautics and Space Administration (1969)).

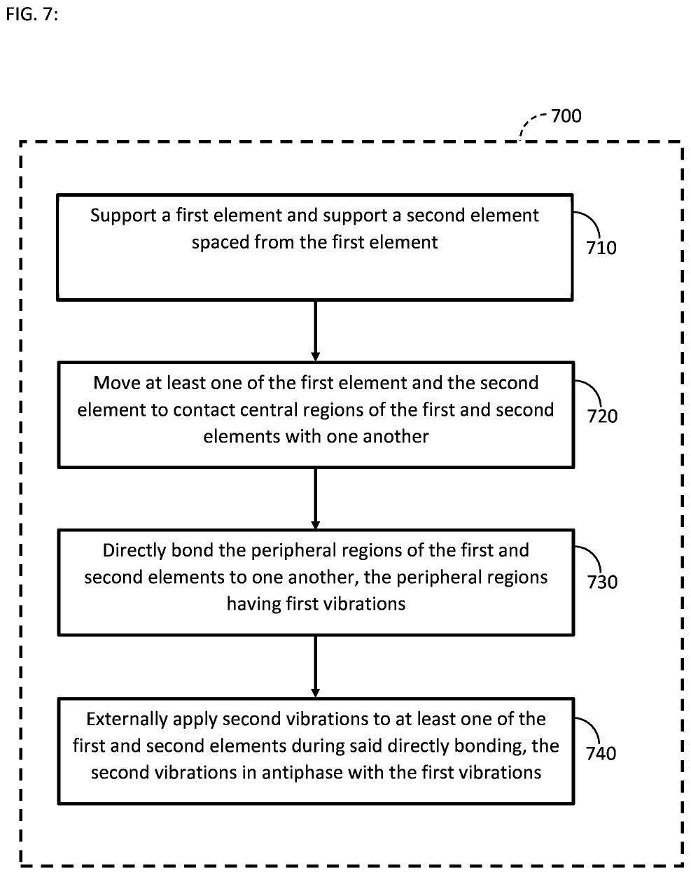

FIG. 7 is a flow diagram of an example method 700 in accordance with certain implementations described herein. While the example method 700 is described herein by referring to the example apparatus 500 of FIGS. 2A, 2B, 5A, and 5B, other apparatuses are also compatible with the example method 700 in accordance with certain implementations described herein.

In an operational block 710, the method 700 comprises supporting a first element 102 and supporting a second element 104 spaced from the first element 102. In an operational block 720, the method 700 further comprises moving at least one of the first element 102 and the second element 104 to contact first regions of the first and second elements 102, 104 with one another (e.g., central regions; center-symmetric regions) while second regions of the first and second elements 102, 104 are not in contact with one another (e.g., peripheral regions; off-center-symmetric regions). The first regions directly bond to one another to form a bond interface. In an operational block 730, the method 700 further comprises directly bonding the second regions of the first and second elements 102, 104 to one another by controllably releasing one of the first element 102 and the second element 104 such that the bond interface 118 and a boundary between the bond interface 118 and the second regions not in contact with one another expands radially away from the first regions. The second regions have first vibrations within a bond initiation region 300 bordering the boundary. In an operational block 740, the method 700 further comprises externally applying second vibrations 532 to at least one of the first and second elements 102, 104 during said directly bonding. The second vibrations are out of phase (e.g., in antiphase) with the first vibrations in the bond initiation region 300.

In certain implementations, the method 700 further comprises receiving information indicative of the first vibrations and, in response to the information, generating the second vibrations 532. For example, receiving the information can comprise calculating, prior to initiating the directly bonding, the first vibrations within the bond initiation region 118 as a function of time (e.g., the information selected from the group consisting of: sizes, thicknesses, and/or materials of the first and second elements 102, 104; dimensions and other properties of the apparatus 500 supporting the first and second elements 102, 104; temperature or other environmental conditions of the first and second elements 102, 104. In certain implementations, the method 700 further comprises receiving feedback information from at least one sensor (e.g., at least one transducer configured to receive and/or analyze signals), the feedback information indicative of conditions during the direct bonding process, and in response to said feedback information, dynamically modifying the second vibrations.

Although commonly used terms are used to describe the systems and methods of certain implementations for ease of understanding, these terms are used herein to be interpreted fairly. Although various aspects of the disclosure are described with regard to illustrative examples and implementations, the disclosed examples and implementations should not be construed as limiting. Conditional language, such as, among others, “can,” “could,” “might,” or “may,” unless specifically stated otherwise, or otherwise understood within the context as used, is generally intended to convey that certain implementations include, while other implementations do not include, certain features, elements and/or steps. Thus, such conditional language is not generally intended to imply that features, elements and/or steps are in any way required for one or more implementations or that one or more implementations necessarily include logic for deciding, with or without user input or prompting, whether these features, elements and/or steps are included or are to be performed in any particular implementation. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

It is to be appreciated that the implementations disclosed herein are not mutually exclusive and may be combined with one another in various arrangements. In addition, although the disclosed methods and apparatuses have largely been described in the context of direct bonding processes, various implementations described herein can be incorporated in a variety of other suitable devices, methods, and contexts.

Language of degree, as used herein, such as the terms “approximately,” “about.” “generally.” and “substantially.” represent a value, amount, or characteristic close to the stated value, amount, or characteristic that still performs a desired function or achieves a desired result. For example, the terms “approximately,” “about.” “generally,” and “substantially” may refer to an amount that is within +10% of, within +5% of, within +2% of, within +1% of, or within +0.1% of the stated amount. As another example, the terms “generally parallel” and “substantially parallel” refer to a value, amount, or characteristic that departs from exactly parallel by +10 degrees, by +5 degrees, by +2 degrees, by +1 degree, or by +0.1 degree, and the terms “generally perpendicular” and “substantially perpendicular” refer to a value, amount, or characteristic that departs from exactly perpendicular by +10 degrees, by +5 degrees, by +2 degrees, by +1 degree, or by +0.1 degree. The ranges disclosed herein also encompass any and all overlap, sub-ranges, and combinations thereof. Language such as “up to.” “at least,” “greater than,” less than,” “between,” and the like includes the number recited. As used herein, the meaning of “a,” “an,” and “said” includes plural reference unless the context clearly dictates otherwise. Also, as used in the description herein, the meaning of “in” includes “into” and “on,” unless the context clearly dictates otherwise.

While the methods and systems are discussed herein in terms of elements labeled by ordinal adjectives (e.g., first, second, etc.), the ordinal adjective are used merely as labels to distinguish one element from another (e.g., one signal from another or one circuit from one another), and the ordinal adjective is not used to denote an order of these elements or of their use.

The invention described and claimed herein is not to be limited in scope by the specific example implementations herein disclosed, since these implementations are intended as illustrations, and not limitations, of several aspects of the invention. Any equivalent implementations are intended to be within the scope of this invention. Indeed, various modifications of the invention in form and detail, in addition to those shown and described herein, will become apparent to those skilled in the art from the foregoing description. Such modifications are also intended to fall within the scope of the claims. The breadth and scope of the invention should not be limited by any of the example implementations disclosed herein, but should be defined only in accordance with the claims and their equivalents.

What is claimed is:

1. A method comprising:
supporting a first element;
supporting a second element spaced from the first element;
moving at least one of the first element and the second element to contact first regions of the first and second elements with one another while second regions of the first and second elements are not in contact with one another, the first regions directly bonding to one another to form a bond interface without adhesive;
directly bonding the second regions of the first and second elements to one another without adhesive by controllably releasing one of the first element and the second element such that the bond interface and a boundary between the bond interface and the second regions not in contact with one another expands radially away from the first regions, the second regions having first vibrations within a bond initiation region bordering the boundary; and
externally applying second vibrations to at least one of the first and second elements during said directly bonding, the second vibrations in antiphase with the first vibrations in the bond initiation region.

2. The method of claim 1, wherein the first element comprises a first substrate comprising first microelectronic elements and the second element comprises a second substrate comprising second microelectronic elements.

3. The method of claim 1, wherein the first element comprises a first bonding surface and the second element comprises a second bonding surface, wherein said directly bonding directly bonds the first bonding surface to the second bonding surface to one another without the adhesive between the first and second bonding surfaces.

4. The method of claim 3, wherein the second vibrations reduce vibrational distortions of at least one of the first and second bonding surfaces during said directly bonding as compared to directly bonding the first bonding surface to the second bonding surface to one another without said externally applying the second vibrations to the at least one of the first and second elements during said directly bonding.

5. The method of claim 4, wherein said directly bonding comprises direct hybrid bonding.

6. The method of claim 3, further comprising receiving information indicative of the first vibrations and, in response to the information, generating the second vibrations.

7. The method of claim 6, wherein said receiving the information comprises calculating, prior to initiating said directly bonding, the first vibrations within the bond initiation region as a function of time.

8. The method of claim 7, wherein said calculating is performed using information selected from the group consisting of: sizes, thicknesses, and/or materials of the first and second elements; dimensions and other properties of an apparatus supporting the first and second elements; temperature or other environmental conditions of the first and second elements.

9. The method of claim 3, further comprising receiving feedback information from at least one sensor, the feedback information indicative of conditions during said directly bonding, and in response to said feedback information, dynamically modifying the second vibrations.

10. A method comprising:
bonding a first element to a second element in a bond initiation region, the bond initiation region having first vibrations; and
externally applying predetermined second vibrations to at least one of the first and second elements during said bonding, the second vibrations configured to reduce distortions from the first vibrations.

11. The method of claim 10, wherein the second vibrations are out of phase with the first vibrations.

12. The method of claim 10, wherein said bonding comprises direct hybrid bonding.

13. An apparatus comprising:
a first substrate support configured to hold a first substrate;
a second substrate support configured to hold a second substrate and to controllably release the second substrate, at least one of the first substrate support and the second substrate support configured to move at least one of the first substrate and the second substrate to contact one another to initiate a bonding process of the first substrate to the second substrate, at least one of the first substrate and the second substrate undergoing first vibrations during the bonding process; and
at least one transducer configured to controllably generate and transmit second vibrations to at least one of the first substrate and the second substrate during the bonding process, the second vibrations configured to reduce vibration-induced distortions of the at least one of the first substrate and the second substrate during the bonding process.

14. The apparatus of claim 13, wherein the at least one transducer is in mechanical communication with at least one of the first substrate support and the second substrate support, the second vibrations propagating from the at least one transducer to at least one of the first substrate and the second substrate.

15. The apparatus of claim 14, wherein the at least one transducer is in direct contact with the at least one of the first substrate and the second substrate such that the second vibrations propagate from the at least one transducer directly to the at least one of the first substrate and the second substrate.

16. The apparatus of claim 14, wherein the second vibrations propagate from the at least one transducer, through at least a portion of the at least one of the first substrate support and the second substrate support, to the at least one of the first substrate and the second substrate.

17. The apparatus of claim 13, wherein the at least one transducer comprises at least one speaker not in mechanical communication with either the first substrate support or the second substrate support, the at least one speaker configured to generate and transmit sonic vibrations through air to at least one of the first substrate and the second substrate, the sonic vibrations configured to generate the second vibrations.

18. The apparatus of claim 13, wherein the at least one transducer comprises at least one piezoelectric transducer.

19. The apparatus of claim 13, wherein the second vibrations are configured to destructively interfere with the first vibrations in a bond initiation region during the bonding process.

20. The apparatus of claim 13, wherein the first vibrations have a predetermined first modal distribution as a function of time during the bonding process and the second vibrations have a second modal distribution as a function of time during the bonding process, at least a portion of the second modal distribution in antiphase to at least a portion of the first modal distribution.

21. The apparatus of claim 20, wherein the first modal distribution as a function of time comprises a first linear superposition of a plurality of vibration modes, each vibration mode having a corresponding amplitude and phase as a function of time and the second modal distribution F₂(t) can comprise a second linear superposition of the plurality of vibrational modes of the first vibrations, but with each vibration mode having substantially equal amplitudes and substantially opposite phases as those of the first vibrations.

22. The apparatus of claim 13, wherein at least one of the first element and the second element has a thickness in a range of 10 μm to 300 μm.

23. The apparatus of claim 13, wherein the at least one transducer is centrally located with respect to the at least one of the first and second elements.
